(19) United States
(12) Patent Application Publication
(10) Pub. No.: US 2008/0079012 A1
(43) Pub. Date: Apr. 3, 2008

(54) Illuminated devices utilizing transparent light active sheet material with integrated light emitting diode (LED), and methods and kit therefor

(75) Inventors: William Dominic Grote, Madison, IN (US); Stanley D. Robbins, Deputy, IN (US)

Correspondence Address: POSZ LAW GROUP, PLC, 12040 SOUTH LAKES DRIVE, SUITE 101, RESTON, VA, 20191, US

(73) Assignee: Grote Industries, Inc., Madison, IN (US)

(21) Appl. No.: 11/902,982

(22) Filed: Sep. 27, 2007

Related U.S. Application Data
(60) Provisional application No. 60/847,935, filed on Sep. 29, 2006.
(60) Provisional application No. 60/847,917, filed on Sep. 29, 2006.

(51) Int. Cl. H01L 33/00; H01L 29/18

(52) U.S. Cl. 257/89; 257/88; 257/E33.045

(57) ABSTRACT

A transparent lighting system for a conveyance includes a transparent light active sheet material and an adhesive disposed on the transparent light active sheet material. The transparent light active sheet material includes top and bottom electrically conductive transparent substrates, a pattern of light emitting diode (LED) chips sandwiched between the electrically conductive transparent substrates, and a non-conductive transparent adhesive material disposed between the top and bottom electrically conductive transparent substrates and the LED chips. The LED chips are preformed before being patterned in the light active sheet material as an unpackaged discrete semiconductor device having an anode p-junction side and a cathode n-junction side. For the LED chips, either the anode or the cathode side is in electrical communication with one of the electrically conductive transparent substrates, and the other of the anode and the cathode side is in electrical communication with the other of the electrically conductive transparent substrates.

### CROSS-REFERENCE TO RELATED APPLICATIONS

This application claims the benefit of the U.S. Provisional Application No. 60/847,935 filed Sep. 29, 2006; and U.S. Provisional Application No. 60/847,917 filed Sep. 29, 2006, both of which are expressly incorporated herein by reference.

### TECHNICAL FIELD

The technical field relates in general to light sources, and more specifically to light sources utilizing a transparent light active sheet material, optionally for conveyances.

### BACKGROUND

In the vehicle lighting industry, illumination can be achieved through the use of various light sources, all of which require a housing, a substrate, or a body composed of a material through which light can pass. Therefore, conventional lamps for illumination must be mounted in areas that do not restrict vision or light.

Transparent stickers can be used, for example, on windows, to display text or graphics. However, stickers cannot emit light or flash to attract attention.

The only lighting technologies that are applied to windows are thin conventional strips of LED chips, neon lighting, and electroluminescent lighting. None of these are transparent, but typically are thin in order to minimize the amount of light blocked by the light source.

In displays where part of the display is to be illuminated, for example instrument clusters, the instrument clusters are created by screen printing on polycarbonate and then using backlighting from individual LED chips or incandescent bulbs. This process is tedious and expensive and results in bulky instrument clusters which are not transparent.

### SUMMARY

Accordingly, one or more embodiments provide a transparent lighting system for a conveyance. The transparent lighting system includes a transparent light active sheet material, and an adhesive disposed on the transparent light active sheet material. The transparent light active sheet material includes top and bottom electrically conductive transparent substrates, a pattern of light emitting diode (LED) chips sandwiched between the electrically conductive transparent substrates, and a non-conductive transparent adhesive material disposed between the top and bottom electrically conductive transparent substrates and the LED chips. The LED chips are preformed before being patterned in the light active sheet material as an unpackaged discrete semiconductor device having an anode p-junction side and a cathode n-junction side. Either of the anode and the cathode side is in electrical communication with one of the electrically conductive transparent substrates and the other of the anode and the cathode side is in electrical communication with the other of the electrically conductive transparent substrates.

One or more other embodiments provide devices and methods for using a transparent lighting sheet on a conveyance. A transparent light active sheet material is provided. An adhesive sheet is disposed on the transparent light active sheet material. The adhesive sheet has a size sufficient to attach the transparent light active sheet material to the conveyance. The transparent light active sheet material with the adhesive sheet disposed thereon is attached to the conveyance. The light active sheet material includes top and bottom electrically conductive transparent substrates, a pattern of light emitting diode (LED) chips sandwiched between the electrically conductive transparent substrates, and a non-conductive transparent adhesive material disposed between the top and bottom electrically conductive transparent substrates and the LED chips. The LED chips are preformed before being patterned in the light active sheet material as an unpackaged discrete semiconductor device having an anode p-junction side and a cathode n-junction side. Either of the anode and the cathode side is in electrical communication with one of the electrically conductive transparent substrates, and the other of the anode and the cathode side is in electrical communication with the other of the electrically conductive transparent substrates.

Still other embodiments provide a lighting system kit for attaching a transparent light sheet to a conveyance. The lit includes a transparent light active sheet material and an adhesive sheet for attaching the transparent light active sheet material to the conveyance. The adhesive sheet has a size sufficient to attach the transparent light active sheet material to the conveyance. Also included are instructions for shaping the transparent light active sheet material and attaching the transparent light active sheet material to the conveyance. The light active sheet material includes top and bottom electrically conductive transparent substrates, a pattern of light emitting diode (LED) chips sandwiched between the electrically conductive transparent substrates, and a non-conductive transparent adhesive material disposed between the top and bottom electrically conductive transparent substrates and the LED chips. The LED chips are preformed before being patterned in the light active sheet material as an unpackaged discrete semiconductor device having an anode p-junction side and a cathode n-junction side. Either of the anode and the cathode side is in electrical communication with one of the electrically conductive transparent substrates, and the other of the anode and the cathode side is in electrical communication with the other of the electrically conductive transparent substrates.

Further, the purpose of the foregoing abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The abstract is neither intended to define the invention of the application, which is measured by the claims, nor is it intended to be limiting as to the scope of the invention in any way.

### BRIEF DESCRIPTION OF THE DRAWINGS

The accompanying figures, where like reference numerals refer to identical or functionally similar elements and which together with the detailed description below are incorporated in and form part of the specification, serve to further illustrate various exemplary embodiments and to explain various principles and advantages in accordance with the embodiments.

FIG. 1 is a perspective exploded view illustrating transparent lighting;

FIG. 2 is a cross sectional diagram corresponding to FIG. 1;

FIG. 3A to FIG. 3D illustrate transparent lighting on a motorcycle windshield;

FIG. 4 is a cross sectional diagram illustrating transparent lighting adhered to an inside of a window;

FIG. 5A to FIG. 5C are cross sectional diagrams illustrating a method of producing the transparent lighting according to FIG. 4;

FIG. 6 is a cross sectional diagram illustrating transparent lighting adhered to an outside of a window;

FIG. 7 is a cross sectional diagram illustrating transparent lighting laminated between two layers of glass;

FIG. 8A to FIG. 8D are cross sectional diagrams illustrating a method of producing the transparent lighting of FIG. 7;

FIG. 9A and FIG. 9B illustrate stop/tail/turn lights on a rear window;

FIG. 10A and FIG. 10B illustrate illuminated words on a window;

FIG. 11A and FIG. 11B illustrate high mount stop lights on a rear window;

FIG. 12A and FIG. 12B illustrate turn signals on a window;

FIG. 13A and FIG. 13B illustrate illuminated advertising signs on a window;

FIG. 14 illustrates various configurations of transparent lighting applied directly to an automobile;

FIG. 15 illustrates a use of transparent lighting behind mirror glass;

FIG. 16 is a cross sectional diagram corresponding to FIG. 15;

FIG. 17A to FIG. 17E are cross sectional diagrams illustrating a method of producing the transparent lighting behind mirror glass according to FIG. 15;

FIG. 18 is a illustration of transparent lighting used with a side view mirror;

FIG. 19 is an illustration of transparent lighting used with a rear view mirror;

FIG. 20 is a cross sectional view of the transparent lighting according to FIG. 19;

FIG. 21 is a cross sectional view of transparent lighting on glass;

FIG. 22 is plan view of the transparent lighting of FIG. 21; and

FIG. 23A to FIG. 23G are cross sectional diagrams illustrating a method of producing the transparent lighting according to FIG. 21 to FIG. 22.

### DETAILED DESCRIPTION

In overview, the present disclosure concerns transparent light active sheet material, lighting systems using transparent light active sheet material, methods of making such light active sheet material and lighting systems, and kits for the same. In the transparent light active sheet material, light emitting diode (LED) chips are integral to the light active sheet material. Such light active sheet material, sometimes referred to as “light sheet,” can be illuminated, transparent, thin, flat and flexible. Moreover, a light sheet does not require housings or hard lenses than can be damaged or cracked. The thin characteristic, flexibility, and transparency of the transparent light sheet can be exploited to provide illuminated devices in various forms for accent, safety, or cosmetic purposes, including without limitation transparent lighting on windows, and illuminated devices. Examples of illuminated devices include interior illumination and exterior illumination such as backlighting, high mount stop lamp (HMSL), center high mount stop lamp (CHMSL), headlamps, fog lamps, stop/tail/turn (STT) lights, front/park/turn (FPT) lights, variants, and the like, used in connection with conveyances, which can optionally be placed on a window. More particularly, various inventive concepts and principles are embodied in systems, devices, and methods therein for providing transparent light active sheet material with integrated LED chips, and devices utilizing the same.

The conveyances of particular interest include automobiles, trucks, motorized vehicles, trains, trailers, air craft, water craft, heavy machinery used for regulated or non-regulated industries such as agricultural, lawn care, mining, snow blowing, and the like, and variants or evolutions thereof.

The instant disclosure is provided to further explain in an enabling fashion the best modes of performing one or more embodiments. The disclosure is further offered to enhance an understanding and appreciation for the inventive principles and advantages thereof, rather than to limit in any manner the invention. The invention is defined solely by the appended claims including any amendments, made during the pendency of this application and all equivalents of those claims as issued.

It is further understood that the use of relational terms such as first and second, and the like, if any, are used solely to distinguish one from another entity, item, or action without necessarily requiring or implying any actual such relationship or order between such entities, items or actions. It is noted that some embodiments may include a plurality of processes or steps, which can be performed in any order, unless expressly and necessarily limited to a particular order; i.e., processes or steps that are not so limited may be performed in any order.

As further discussed herein below, various inventive principles and combinations thereof are advantageously employed to simplify the process of manufacturing light sources, to reduce breakage of lamps, to provide easier handling and mounting of light sources, where the light sources are operable in connection with a conveyance.

Light active sheet material can be manufactured on electrically conductive transparent material, for example an indium tin oxide (ITO) film. Conductors can be provided, for example by silver ink printed in narrow lines on the transparent film, or by another ITO film, to provide current to individual light emitting diode (LED) chips without significantly impacting the transparency of the light active sheet material. Doing so allows the design and manufacture of a light active sheet material through which light can pass, and which is transparent over most of the light sheet surface.

The transparency of the light sheet can be capitalized on in connection with various lighting such as lights applied to windows. A driver can see through such a transparent light sheet. Lighting can include illuminated logos, stop lamps, turn lamps, and emergency lighting. Such lighting can be disposed on or in windows, for example.

Optionally, opaque material can be printed onto a transparent light sheet to control the areas which are illuminated. This allows thin panels for instrumentation, for example.

A transparent light sheet can be added directly to the surface of a conveyance, to provide illumination in a particular direction, or to exploit the transparency of the light sheet.

Further in accordance with exemplary embodiments, light active sheet material can be provided which is transparent. Vehicles, for example, can utilize the light active sheet material in transparent applications. The light active sheet material optionally can provide a wide angle of light, can provide flexible lamps, and can be laminated.

The transparency of light active sheet material allows two or more light sheets to be stacked. Light sheets, or LED chips embedded therein, can emit different colors. Because the light sheets are transparent, the colors can show through the other light sheets in the stack.

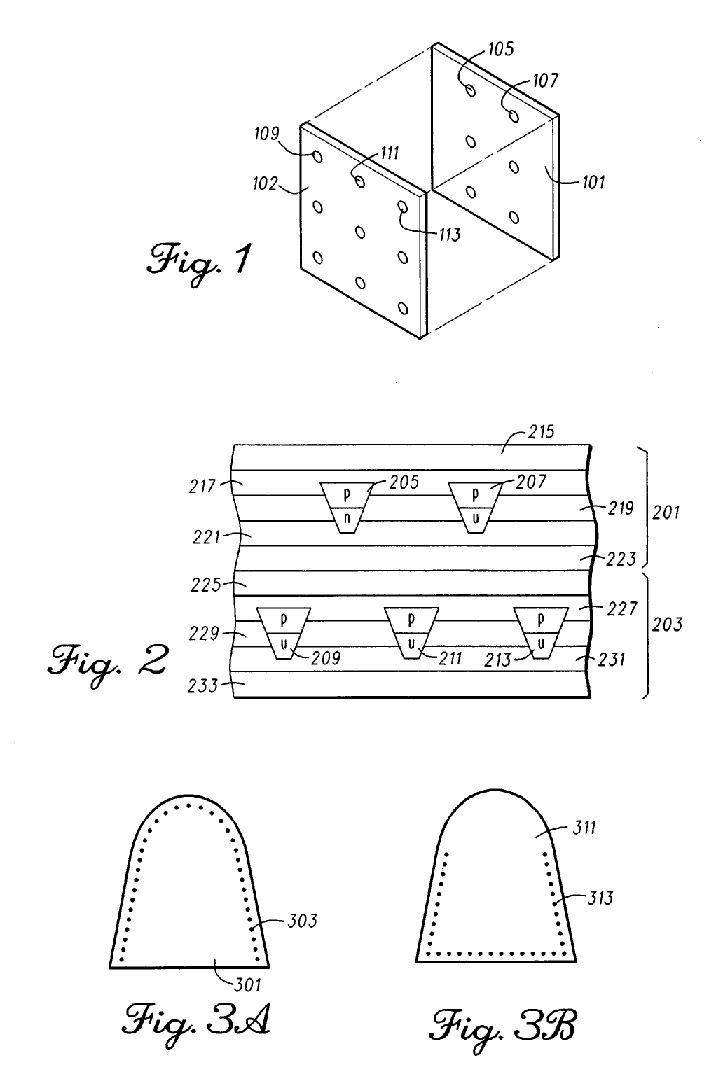

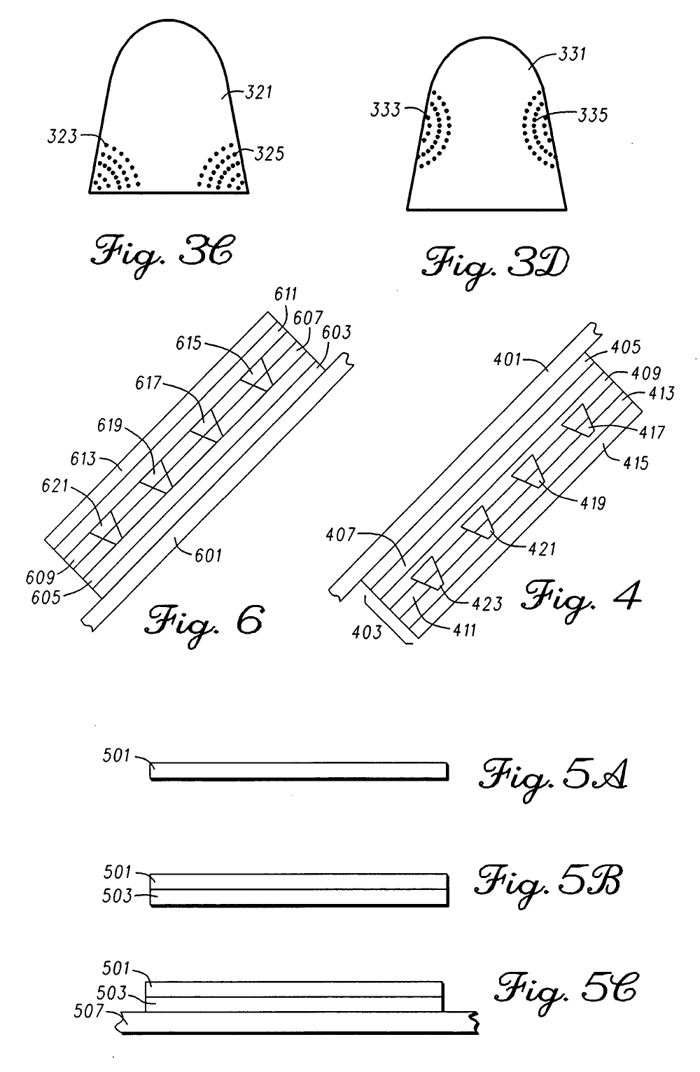

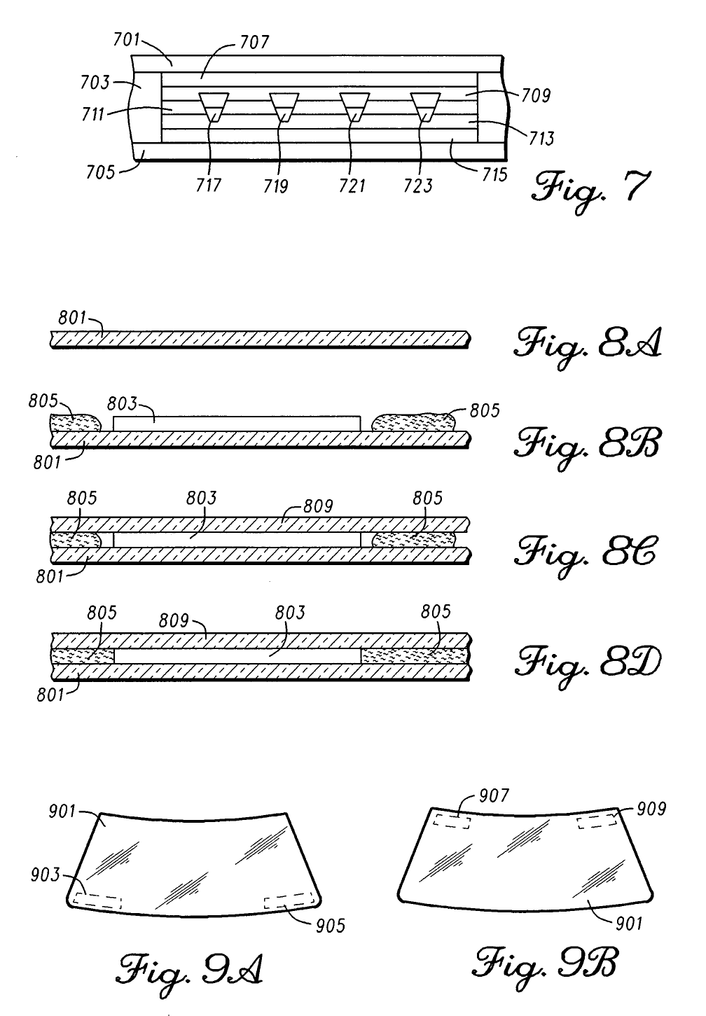

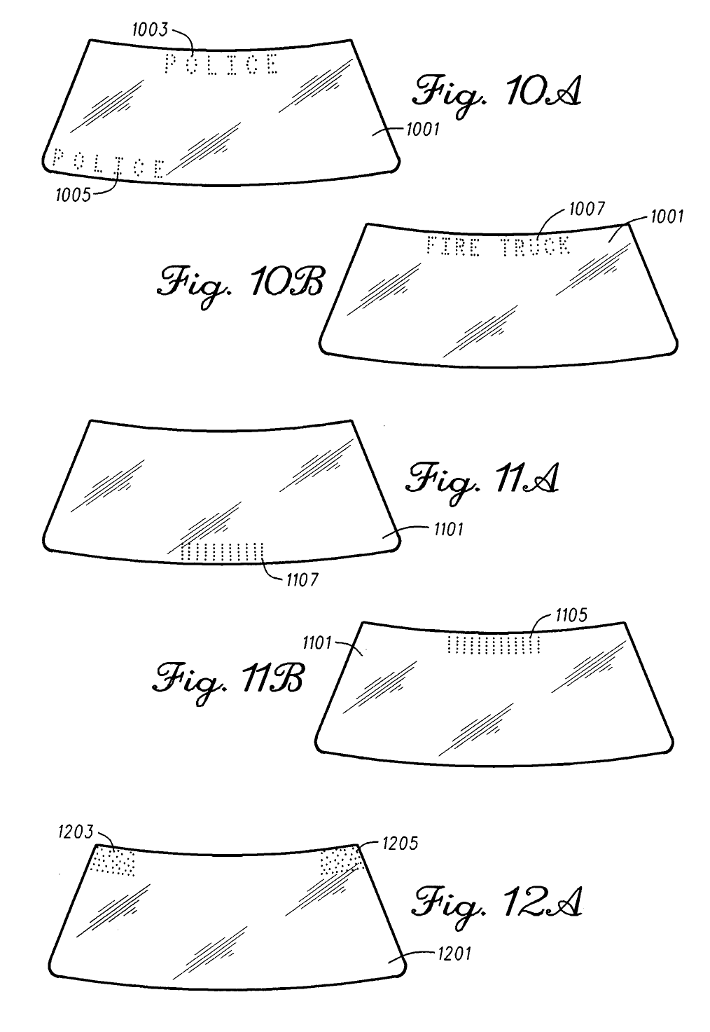

FIG. 1 and FIG. 2 illustrate two sheets of light active sheet material which are stacked. FIG. 1 is an exploded view of the two sheets, and FIG. 2 illustrates layers in the stack of light active sheet materials.

Referring now to FIG. 1, a perspective exploded view illustrating transparent lighting will be discussed and described. In this figure are illustrated a first transparent light sheet 101, and a second transparent light sheet 103. The first transparent light sheet 101 includes LED chips 105, 107 embedded therein. The second transparent light sheet 103 also includes LED chips 109, 111, 113 embedded therein. The LED chips 105, 107, 109, 111, 113 are integrated in the electronics of the respective light sheets 101, 103 as further described below.

The first transparent light sheet 101 can be stacked on top of the second transparent light sheet 103. In this illustration, the LED chips 105, 107 in the first transparent light sheet 101 are offset from the LED chips 109, 111, 113 in the second transparent light sheet 103. Consequently, light emitted from LED chips in one light sheet can travel through the other transparent light sheet, without the light from one light sheet being significantly blocked by LED chips in the other light sheet.

Accordingly, there can be provided a lighting system wherein the first and second patterns are the same and the first and second light active sheet materials are disposed so that the first and second patterns are offset.

The transparency of the light active sheet material can allow several light sheets to be stacked on top of each other in order to provide multi-color displays. Because the light sheets are transparent, the colors show through the stacks of light sheet.

The first and second transparent light sheets 101, 103 can be connected to a power source, such as an electrical harness of a conveyance on which the stacked light sheets are mounted, via an electrical connector (not illustrated) to the conductive substrates or conductors which are an integral part of the light active sheet material, as further discussed below. The first and second transparent light sheets 101, 103 can be selectively activated, together or separately.

Accordingly, there can be provided a lighting system, wherein the first and second patterns are configured to be separately activateable.

Referring now to FIG. 2, a cross sectional diagram corresponding to FIG. 1 will be discussed and described. A first light sheet 201 and a second light sheet 203 are illustrated. The first light sheet 201 includes LED chips 205, 207, a first transparent substrate 215, a first electrically conductive transparent layer 217, a first adhesive material 219, a second electrically conductive transparent layer 221, and a second transparent substrate 223. The second light sheet 201 includes LED chips 209, 211, 213, a third transparent substrate 225, a third electrically conductive transparent layer 227, a second adhesive material 229, a fourth electrically conductive transparent layer 231, and a fourth transparent substrate 233.

In this illustration, the LED chips 205, 207 in the first light sheet 201 are spaced vertically from and offset between the LED chips 209, 211, 213 in the second light sheet 203. Thus, light emitted from the LED chips 209, 211, 213 in the second light sheet 203 can pass through the first light sheet 201 with little obstruction by the LED chips 205, 207 in the first light sheet 201.

In this illustration, two light sheets 201, 203 are stacked together, so that the transparent substrates 223, 225 face each other. One of the adjacent transparent substrates 223, 225 (referred to as an “intermediate” transparent substrate) can be omitted from the stacked light sheets. However, if the transparent light sheet is produced as a single light sheet, rather than as a double light sheet, it can be more convenient to include both transparent substrates 223, 225.

The first, second, third and fourth substrates 215, 223, 225, 233 can be formed of a transparent or translucent material, which can be non-conductive. The material of the second substrate 223 advantageously can be flexible. Appropriate materials for use as the first, second, third and fourth substrates 215, 223, 225, 233 include transparent or translucent plastics, for example, polymers such as, for example, polyethylene terephthalate (PET) and polyethylene.

The first, second, third and fourth electrically conductive transparent layers 217, 221, 227, 231 can be formed of an electrically conductive material which is also optically transparent or translucent. An appropriate material is a conducting metal oxide, for example an indium tin oxide (ITO) film (as illustrated), a carbon nanotube conductive film, an aluminum-doped zinc oxide film, and/or a conductive polymer layer such as PEDOT:PSS (poly(3,4-ethylenedioxythiophene) poly(styrenesulfonate))and/or PEDOT (poly(3,4-ethylenedioxythiophene)) available from, for example, Agfa or H. C. Starck. The electrically conductive transparent layer is not illustrated to scale, and is typically a very thin layer applied to the respective first, second, third or fourth substrate.

Each of the LED chips 205, 207, 209, 211, 213 has a p-side and an n-side and/or light-to-energy semiconductor layered particles, wherein the n-side and the p-side correspond to charge donor and charge acceptor layers. The LED chips 205, 207, 209, 211, 213 are oriented to be driven with the same polarity electrical energy. Each of the LED chips 205, 207 in the first light sheet 201 is in electrical contact with both of the first and second electrically conductive transparent layers 217, 221. Similarly, each of the LED chips 209, 211, 213 in the second light sheet 203 is in electrical contact with both of the third and fourth electrically conductive transparent layers 227, 231. Appropriate LED chips are widely available commercially. The LED chips 205, 207, 209, 211, 213 are patterned on the conductors, in a pre-determined (non-random) pattern. For example, a density of the LED chips can be determined according to a desired brightness. As another example, a distribution of the LED chips and/or LED chips of specific colors can be determined according to a desired lighting pattern.

The first adhesive material 219 in the first light sheet 201 is disposed to fill gaps between the patterned LED chips 205, 207, and gaps between the first and second electrically conductive transparent layers 217, 221. The first adhesive material 219 also mechanically holds the LED chips 205, 207, substrates and electrically transparent conductive layers 215, 217, 221, 223 together. The first adhesive material 219 electrically isolates the first electrically conductive transparent layer 217 from the second electrically conductive transparent layer 221, and therefore the first adhesive material can be formed of a non-conductive adhesive material. The second adhesive material 229 in the second light sheet 203 is disposed in a similar manner, but within the second light sheet 203. The second adhesive material also is formed of a non-conductive adhesive material. The first and second adhesive materials 219, 229 further can be transparent or translucent. An appropriate material for use as the first and/or second adhesive materials 219, 229 is a hot melt adhesive, for example an EVA (ethylene vinyl acetate) adhesive, a polyurethane adhesive, a polyolefin adhesive, a polyamide adhesive, or similar material.

Accordingly, a lighting system can include a first light active sheet material, a second light active sheet material in continuous contact with the first light active sheet material, and an intermediate transparent substrate disposed between the first and second light active sheet material. The first light active sheet material can include first and second electrically conductive transparent substrates, a first pattern of light emitting diode (LED) chips sandwiched between the first and second electrically conductive transparent substrates, and a first non-conductive transparent adhesive material disposed between the first and second electrically conductive transparent substrates and the LED chips in the first pattern. The second light active sheet material can include third and fourth electrically conductive transparent substrates, a second pattern of LED chips sandwiched between the third and fourth electrically conductive transparent substrates, and a second non-conductive transparent adhesive material disposed between the third and fourth electrically conductive transparent substrates and the LED chips in the second pattern. The LED chips can be preformed before being patterned in the light active sheet material as an unpackaged discrete semiconductor device having an anode p-junction side and a cathode n-junction side, wherein either of the anode and the cathode side is in electrical communication with one of the electrically conductive transparent substrates and the other of the anode and the cathode side is in electrical communication with the other of the electrically conductive transparent substrates.

Further accordingly, there is a method of providing a conveyance with a lighting system, including providing such a lighting system, mounting the lighting system on the conveyance, and electrically connecting the lighting system to an electrical wiring harness of the conveyance.

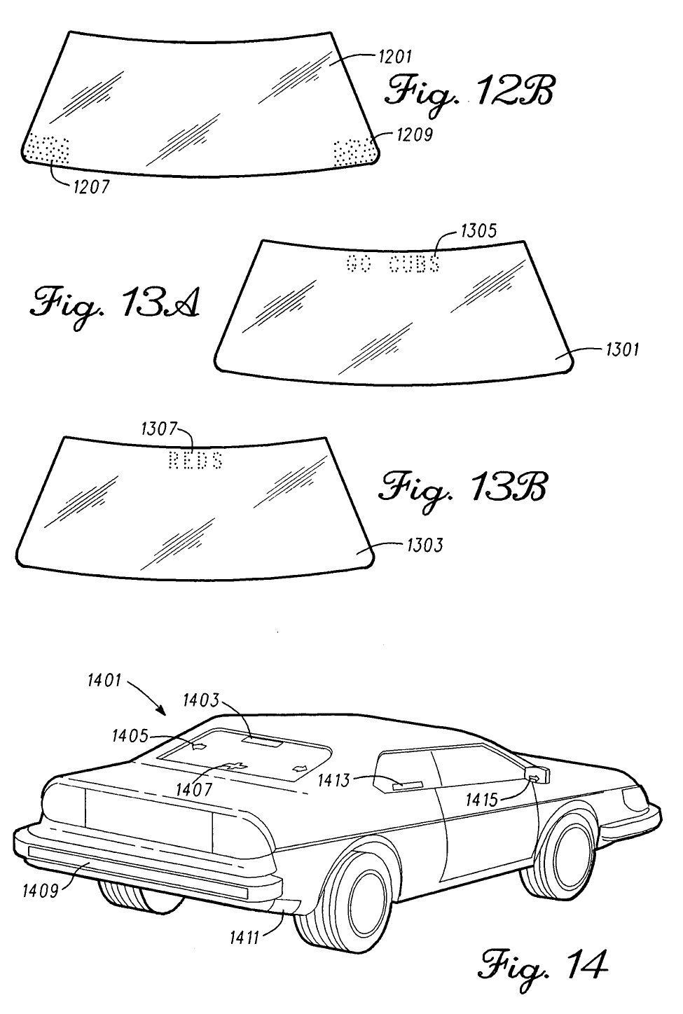

Referring now to FIG. 3A to FIG. 3D, transparent lighting on a motorcycle windshield will be discussed and described. The transparency of a light active sheet material enables it to be used to create accent lighting for a windshield. For example, a light active sheet material can be cut into strips and these can be formed along the edges of the windshield. A light active sheet material can be used to create turn signals on a windshield. The LED chips in the transparent light active sheet materials emit light from top and bottom, so these turn signals can be visible from the front and rear of the motorcycle (depending on the design of the motorcycle and size of its occupant(s)). Various patterns can be used, as illustrated in FIG. 3A to FIG. 3D.

In FIG. 3A, a windshield 301 includes a light sheet 303 with LED chips disposed so as to outline the top and side edges of the windshield 301. In FIG. 3B, a windshield 311 includes a light sheet 313 with LED chips disposed so as to outline the bottom and side edges of the windshield 311.

In FIG. 3C, a windshield 321 includes a first light sheet 323 with LED chips disposed so as to fill a first lower corner of the windshield 321, and a second light sheet 325 with LED chips disposed so as to fill a second lower corner 325 of the windshield 321. The first and second light sheets 323, 325 at opposite corners can be selectively lit for use as turn signals.

In FIG. 3D, a windshield 331 includes a first light sheet 333 with LED chips disposed so as to fill an upper left part of the windshield 331, and a second light sheet 335 with LED chips disposed so as to fill an upper right part of the windshield 321. The first and second light sheets 333, 335 at opposite sides of the windshield can be lit selectively and/or separately, for example for use as turn signals.

In the above illustrations of FIG. 3A to FIG. 3D, the light sheet can be disposed on the inside or the outside of the windshield, or can be incorporated into the windshield, as further discussed below.

FIG. 4 and FIG. 6 illustrate various applications of light active sheet material on the inside or outside, respectively, of glass such as a window. FIG. 5A to FIG. 5C illustrates a process of applying the light active sheet material shown in FIG. 4.

Referring now to FIG. 4, a cross sectional diagram illustrating transparent lighting adhered to an inside of a window will be discussed and described. In this illustration, a light active sheet material 403 is adhered to glass 401 using an adhesive 405, so that the light active sheet material 403 is on an interior side of the window.

In this example, the light active sheet material 403 can be mounted on the back window, front window, or side window in an interior of a conveyance. The adhesive 405 used to mount the light active sheet material 403 to the glass can be a transparent adhesive sheet (for example, adhesive tape), adhesive spray, or glue, for example.

The light active sheet material 403 can be provided in a desired location on the window. Several examples using the light active sheet material in connection with conveyances are discussed herein.

The light active sheet material 403 can include first and second transparent substrates 407, 415, first and second electrically conductive transparent substrates 409, 413, an adhesive material 411, and LED chips 417, 419, 421, 423. An appropriate light sheet is discussed in connection with FIG. 2, for example. Any other transparent light active sheet material can alternatively be used, such as, for example, the light sheet discussed in connection with FIG. 21 and FIG. 22 herein.

Accordingly, there can be provided a transparent lighting system for a conveyance, including a transparent light active sheet material; and an adhesive disposed on the transparent light active sheet material, wherein the transparent light active sheet material comprises top and bottom electrically conductive transparent substrates, a pattern of light emitting diode (LED) chips sandwiched between the electrically conductive transparent substrates, and a non-conductive transparent adhesive material disposed between the top and bottom electrically conductive transparent substrates and the LED chips, wherein the LED chips are preformed before being patterned in the light active sheet material as an unpackaged discrete semiconductor device having an anode p-junction side and a cathode n-junction side, wherein either of the anode and the cathode side is in electrical communication with one of the electrically conductive transparent substrates and the other of the anode and the cathode side is in electrical communication with the other of the electrically conductive transparent substrates.

Furthermore, a method of providing a conveyance with a transparent lighting system can include providing a transparent lighting system as described herein, mounting the transparent lighting system on the conveyance, and electrically connecting the transparent lighting system to an electrical wiring harness of the conveyance.

Referring now to FIG. 5A to FIG. 5C, cross sectional diagrams illustrating a method of producing the transparent lighting according to FIG. 4 will be discussed and described. In FIG. 5A, the light active sheet material 501 is provided in a desired shape and size. In FIG. 5B, an adhesive 503 is disposed on the light active sheet material 501, with a first surface of the adhesive 503 facing the light active sheet material 501 and an opposite surface of the adhesive 503 facing away from the light active sheet material 501. Alternatively, the adhesive 503 can be disposed on a part of a window to which the light active sheet material 501 is to be attached.

In FIG. 5C, the light active sheet material 501 with adhesive 503 is mounted on a glass 507. The light active sheet material 501 can be connected to a power source, such as an electrical harness of a conveyance on which the glass is mounted, via an electrical connector (not illustrated) connected to the conductive substrate in the light active sheet material 501.

Accordingly, a method for using a transparent lighting sheet on a conveyance can include providing a transparent light active sheet material; disposing an adhesive sheet on the transparent light active sheet material, wherein the adhesive sheet has a size sufficient to attach the transparent light active sheet material to the conveyance; and attaching, to the conveyance, the transparent light active sheet material with the adhesive sheet disposed thereon. The light active sheet material comprises top and bottom electrically conductive transparent substrates, a pattern of light emitting diode (LED) chips sandwiched between the electrically conductive transparent substrates, and a non-conductive transparent adhesive material disposed between the top and bottom electrically conductive transparent substrates and the LED chips. The LED chips are preformed before being patterned in the light active sheet material as an unpackaged discrete semiconductor device having an anode p-junction side and a cathode n-junction side. Either of the anode and the cathode side is in electrical communication with one of the electrically conductive transparent substrates and the other of the anode and the cathode side is in electrical communication with the other of the electrically conductive transparent substrates.

Further accordingly, the method can include shaping the transparent light active sheet material prior to attaching the transparent light active sheet material to the conveyance.

Furthermore, the transparent light active sheet material can be shaped as a lighting system for the conveyance (for example as further described herein), wherein the LED chips have red or white or amber or blue or green colors, wherein the color of LED chips in the pattern are disposed in a pattern for use as one or more lighting systems, wherein the lighting system is attached to a respective location on the conveyance.

Accordingly, there can be provided a lighting system kit for attaching a transparent light sheet to a conveyance. The kit can include a transparent light active sheet material, an adhesive sheet for attaching the transparent light active sheet material to the conveyance, wherein the adhesive sheet has a size sufficient to attach the transparent light active sheet material to the conveyance, and instructions for shaping the transparent light active sheet material and attaching the transparent light active sheet material to the conveyance.

Referring now to FIG. 6, a cross sectional diagram illustrating transparent lighting adhered to an outside of a window will be discussed and described. In this illustration, a light active sheet material is adhered to glass 601 using an adhesive 603, so that the light active sheet material is on an exterior side of the window, for example, on an outside of the window of a conveyance.

The light active sheet material can be used on the back window, front window, or side window. The adhesive 603 can be a transparent adhesive sheet (such as an adhesive tape), adhesive spray, or glue, for example.

The light active sheet material can be provided in a desired location on the window. Several examples are discussed herein.

The light active sheet material can include first and second transparent substrates 613, 605, first and second electrically conductive transparent substrates 611, 607, an adhesive material 609, and LED chips 615, 617, 619, 621. An appropriate light sheet is discussed in FIG. 2, for example. Any other transparent light active sheet material can alternatively be used, for example, the light sheet discussed in connection with FIG. 21 and FIG. 22 herein.

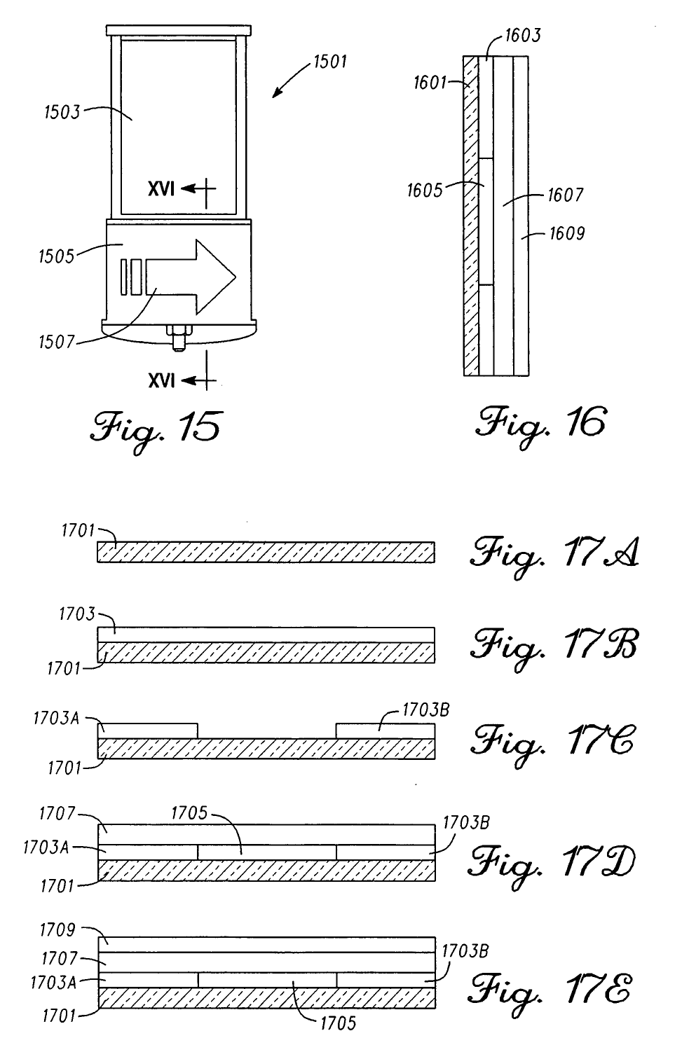

FIG. 7 and FIG. 8A to FIG. 8D illustrate transparent lighting laminated between two layers of glass. FIG. 7 illustrates the layers (including the glass and exemplary layers in the light active sheet material), and FIG. 8A to 8D illustrate a process of laminating the transparent lighting between the two layers of glass.

Referring now to FIG. 7, a cross sectional diagram illustrating transparent lighting laminated between two layers of glass will be discussed and described. In this illustration, the light active sheet material can include first and second transparent substrates 707, 715, first and second electrically conductive transparent substrates 709, 713, an adhesive material 711, and LED chips 717, 719, 721, 723. An appropriate light sheet is discussed in connection with FIG. 2, for example. Any other transparent light active sheet material can alternatively be used, for example, the light sheet discussed in connection with FIG. 21 and FIG. 22 herein.

The light active sheet material is sandwiched between first and second layers of glass 701, 705. A laminate material 703 is disposed around the light active sheet material and serves to mechanically attach together the first and second layers of glass 701, 705 and the light active sheet material. Conventional materials can be used as the laminate material, and conventional techniques can be used to laminate the glass layers together. The laminate material is transparent.

Accordingly, glass with an embedded lighting system includes a transparent light active sheet material, a first clear substrate, the transparent light active sheet material being disposed on the first clear substrate, wherein the first clear substrate is formed of glass, and a second clear substrate disposed on the transparent light active sheet material so as to cover the transparent light active sheet material and the first clear substrate. The first and second clear substrates are laminated together with the transparent light active sheet material sandwiched between. The light active sheet material comprises top and bottom electrically conductive transparent substrates, and a pattern of light emitting diode (LED) chips sandwiched between the electrically conductive transparent substrates. The LED chips are preformed before being patterned in the light active sheet material as an unpackaged discrete semiconductor device having an anode p-junction side and a cathode n-junction side, wherein either of the anode and the cathode side is in electrical communication with one of the electrically conductive transparent substrates and the other of the anode and the cathode side is in electrical communication with the other of the electrically conductive transparent substrates.

The ability to laminate light active sheet material between layers of glass can allow various configurations of lighting devices to be incorporated into the glass. For example, a light active sheet material light, such as a CHMSL or a turn signal, can be laminated between glass. Moreover, the light active sheet material can be laminated between layers of glass at the same time as a radio antenna or defroster.

Also, the glass can take a desired form, or can be incorporated into a mirror. Accordingly, in the glass with the embedded lighting system, the first and second clear substrates can be shaped as a window or mirror for a conveyance.

Also, one or more embodiments can provide a method of providing a conveyance with a lighting system embedded in glass. The method can include providing a glass with an embedded light system as discussed above, mounting the glass with the embedded lighting system on the conveyance, electrically connecting the embedded lighting system to an electrical wiring harness of the conveyance.

Referring now to FIG. 8A to FIG. 8D, cross sectional diagrams illustrating a method of producing the transparent lighting of FIG. 7 will be discussed and described. In FIG. 8A, a first layer of glass 801 is provided.

As illustrated in FIG. 8B, a light active sheet material 803 is provided on the first layer of glass 801. Also, a laminate material 805 such as a transparent adhesive appropriate for use in lamination of glass is provided on the first layer of glass 810, adjacent to the light active sheet material 803.

A second layer of glass 809 is then placed on and covers the light active sheet material 803 and the laminate material 805, as illustrated in FIG. 8C. The first and second layers of glass 801, 809 and the light active sheet material 803 can then be laminated together, for example by application of pressure and/or heat. FIG. 8D illustrates the transparent lighting formed by the light active sheet material 803 laminated between the two layers of glass 801, 809, where the laminate material 805 has flowed to form a tight laminate.

Various lights and illuminated signs can be provided in windows of conveyances. Because most of the light active sheet material is transparent (e.g., with the exception of the LED chips), almost none of the view through the window is obscured. The transparent light sheet can be mounted on or in or adhered directly onto any of a conveyance's interior or exterior surfaces. Because the light sheet is transparent, it is visually discreet. Because of the light sheet's flexibility, the light sheet can readily conform to any surface contour. These surfaces include front windows, rear windows, side mirrors, sun visors, bumper guards, interior rear view mirror, and exterior body panels, by way of example. Moreover, the transparent nature of the light sheet does not obstruct a driver's view. Furthermore, the flexible nature of the light sheet allows the light sheet to be directly mounted on any surface without modification to the surface or the light sheet.

Accordingly, a method of manufacturing glass with an embedded lighting system includes providing a transparent light active sheet material, disposing the transparent light active sheet material on a first clear substrate, wherein the first clear substrate is formed of glass, disposing a laminate material around the transparent light active sheet material on the first clear substrate, covering the transparent light active sheet material on the first clear substrate with a second clear substrate, and laminating the first and second clear substrates together with the transparent light active sheet material and laminate material sandwiched between. The light active sheet material comprises top and bottom electrically conductive transparent substrates, a pattern of light emitting diode (LED) chips sandwiched between the electrically conductive transparent substrates, and a non-conductive transparent adhesive material disposed between the top and bottom electrically conductive transparent substrates and the LED chips. The LED chips are preformed before being patterned in the light active sheet material as an unpackaged discrete semiconductor device having an anode p-junction side and a cathode n-junction side, wherein either of the anode and the cathode side is in electrical communication with one of the electrically conductive transparent substrates and the other of the anode and the cathode side is in electrical communication with the other of the electrically conductive transparent substrates.

FIG. 9A, FIG. 9B, FIG. 10A, FIG. 10B, FIG. 11A, FIG. 11B, FIG. 12A, FIG. 12B, FIG. 13A, and FIG. 13B illustrate various applications of the transparent light active sheet material in various configurations in connection with an automobile window. In these examples, an adhesive can be applied to the transparent light active sheet material or a front, rear or side window, and the light active sheet material can be applied to the window. An appropriate transparent light active sheet material includes those discussed in connection with FIG. 4, FIG. 6, FIG. 7, FIG. 21 and FIG. 22. FIG. 14 also illustrates various uses of transparent lighting on an automobile. These principles can be extended to other conveyances, as well.

Referring now to FIG. 9A and FIG. 9B, stop/tail/turn (STT) lights on a rear window will be discussed and described. In FIG. 9A, STT lights 903, 905 are disposed at lower corners of a window 901. In FIG. 9B, STT lights 907, 909 are disposed at upper corners of the window 901.

Referring now to FIG. 10A and FIG. 10B, illuminated words on a window will be discussed and described. Here, the light active sheet material is trimmed to be printed letters or words, or the LED chips in the light active sheet material are disposed in a pattern of printed letters or words. Because the light active sheet material is transparent, the printed letters or words need not be visible until the LED chips in the light active sheet material are energized. In FIG. 10A, a first and a second light active sheet material 1003, 1005 with the words “POLICE” is disposed at the center top and lower left corner of a window 1001 of the automobile. In FIG. 10B, a light active sheet material 1007 with the words “FIRE TRUCK” is disposed at the center top of a window 1001 of the automobile.

Referring now to FIG. 11A and FIG. 11B, high mount stop lamps (HMSL) on a rear window will be discussed and described. A HMSL (or center high mount stop lamp (CHMSL)) made of transparent light sheet allows the HMSL to be transparent so that the driver can see through the HMSL when the light sheet is not energized. In FIG. 11A, a HMSL 1107 is disposed at the bottom of a window 1101. In FIG. 11B, a HMSL 1105 is disposed at a top of the window 1101.

Referring now to FIG. 12A and FIG. 12B, turn signals on a window will be discussed and described. In FIG. 12A, high mount turn signals 1203, 1205 are disposed at upper corners of a window 1201. In FIG. 12B, turn signals 1207, 1209 are disposed at lower corners of the window 1201. Because the turn signals are made of transparent light sheet, they need not be visible until the LED chips in the light sheet are energized.

Referring now to FIG. 13A and FIG. 13B, illuminated advertising signs on a window will be discussed and described. The light active sheet material can be trimmed to the desired advertising logo, printed words, or design; alternatively the LED chips in the light active sheet material can be disposed in a pattern of the logo, printed words, or the design. In FIG. 13A, a light active sheet material 1305 with the slogan “GO CUBS!” is disposed at the center top of a window 1301 of the automobile. In FIG. 13B, a light active sheet material 1307 with the words “REDS”, is disposed at the center top of a window 1303 of the automobile.

According to various embodiments, therefore, the transparent light active sheet material is formed as an advertisement for an automobile, and the LED chips in the pattern are disposed in a pattern for use as one or more advertisements.

Referring now to FIG. 14, various configurations of a transparent lighting applied directly to an automobile will be discussed and described. There is illustrated an automobile 1401 with an emergency strobe light 1403, turn lights 1405, illuminated logo 1407, illuminated transparent accent lighting 1409, illuminated transparent under-mount lighting, illuminated transparent advertisement 1413, and mirror with turn signal 1415. Using extensions of these examples, one can appreciate the different locations on which a light active sheet material can be used in an automobile or other conveyance.

Appropriate transparent light active sheet materials include those discussed in connection with FIG. 4, FIG. 6, FIG. 7, FIG. 21 and FIG. 22. The transparent lighting behind mirror glass discussed in more detail in connection with FIG. 15 can advantageously be used as the mirror with turn signal 1415.

A light active sheet material of any desired size, with a sufficiently high density of LED chips, can be adhered directly to any surface of a conveyance in the direction that illumination is needed.

The surfaces to which the light active sheet material is applied can be transparent surfaces (for example, windows) or non-transparent surfaces (for example, body panels).

A transparent light active sheet material adhered to a non-transparent surface allows the color of the surface to which it is adhered to show through. Alternatively, the light active sheet material can incorporate one or more color(s) (in any of the substrates and/or in the adhesive material), which will allow some of the surface color below the light sheet to show through. If the LED chips in the light active sheet material are colored, then the color of the LED chips will be visible when the light active sheet material is energized.

According to one or more embodiments, therefore, the transparent light active sheet material is formed as a lighting system for an automobile or motorcycle, wherein the LED chips have red or white or amber or blue or green colors, and wherein the color of LED chips in the pattern are disposed in a pattern for use as one or more lighting devices, wherein the lighting devices are: a rear window lighting system, a side window lighting system, a turn signal lighting system, a high mount stop lighting system, a center high mount stop lighting system, a windshield outlining system, a side marker lamp system, or an emergency strobe light.

FIG. 15, FIG. 16 and FIG. 17A to FIG. 17E discuss the use of transparent lighting embedded in a mirror. FIG. 15 illustrates the mirror with embedded transparent lighting, FIG. 16 illustrates a cross section of the mirror, and FIG. 17A to FIG. 17E illustrate a process of making the mirror.

Referring now to FIG. 15, a use of transparent lighting behind mirror glass will be discussed and described. A mirror glass can be masked in the shape of an arrow, so that when a mirror coating (such as silver or chrome) is applied to the rear of the glass, the masked portion is clear. A light active sheet material can be bonded to the back of the mirror glass covering the marked portion. The light active sheet material can be connected to a power source, such as an electrical harness of an automobile, so that the masked portion is lit.

In this example, a side view mirror 1501 includes a mirror portion 1503 and a turn signal portion 1505. The turn signal portion includes an arrow 1507 which can be selectively illuminated, for example flashed as a turn signal light. The side view mirror 1501 can be mounted on a conveyance, and connected to a power source, for operate for example as the turn function of the conveyance.

Accordingly, in the mirror, the uncoated area can be shaped as a turn indicator.

Conventional signal-systems integrated into vehicle mirrors, in contrast, either place a light around the mirror, or use individual LED chips with the mirror. In the manner described above, however, the LED chips can be integrated into the mirror.

Accordingly, a method of providing a conveyance with a lighting system embedded in a mirror includes providing a mirror with an embedded lighting system as discussed above, mounting the mirror with the embedded lighting system on the conveyance, and electrically connecting the embedded lighting system to an electrical wiring harness of the conveyance.

Referring now to FIG. 16, a cross sectional diagram corresponding to FIG. 15 will be discussed and described. Glass 1601 or any other clear substrate has a mirror coating 1603 applied on one of its sides, in accordance with conventional techniques. The mirror coating 1603 has a masked portion 1605 where the glass 1601 remains clear. The glass 1601 is applied with the mirror coating 1603 facing a light sheet 1607; the light sheet is disposed behind at least the masked portion 1605, and can extend to the edges of the glass 1601. The glass 1601 is mounted on a mirror base 1609 with the light sheet 1607 sandwiched between the mirror coating 1603 and the mirror base 1609.

The light sheet 1607 which is used can have a grid of LED chips, or can have LED chips patterned so as to correspond to the shape of the masked portion 1605. Materials appropriate for use as the mirror base 1609 include, for example, a metal or plastic housing for the mirror. Materials appropriate for use as the mirror coating 1603 include silver or chrome or any other material appropriate for creating a reflective mirror. Materials appropriate for use as the light active sheet material 1607 include those discussed in connection with FIG. 4, FIG. 6, FIG. 7, FIG. 21 and FIG. 22.

Accordingly, a mirror with an embedded lighting system can include a clear substrate, wherein the clear substrate is to be used as mirror; a mirror coating formed on the clear substrate, with an opening formed therein to provide an uncoated area of the clear substrate conforming to a shape of a light; a light active sheet material, the light active sheet material being disposed on the clear substrate on the side of the mirror coating, so as to at least cover the uncoated area; and a mirror base disposed on the light active sheet material so as to cover the light active sheet material and the clear substrate.

Referring now to FIG. 17A to FIG. 17E, cross sectional diagrams illustrating a method of producing the transparent lighting behind mirror glass according to FIG. 15 will be discussed and described. In FIG. 17A, a clear substrate 1701 such as glass is provided. In FIG. 17B, a layer of silver coating 1703 is applied to the clear substrate 1701.

In FIG. 17C, the silver coating is etched to provide a masked portion in a desired shape between separated coating portions 1703A, 1703B. Alternatively, the masked portion can be provided by applying a mask over the clear substrate 1701 prior to applying the layer of silver coating 1703.

In FIG. 17D, a light active sheet material 1707 is disposed over the coating portions 1703A, 1703B, so that the light active sheet material 1707 covers at least the masked portion 1705.

In FIG. 17E, a mirror base 1709 is applied over the light active sheet material 1707, or the clear substrate 1701 is mounted on the mirror base 1709, so that the mirror base 1709 covers the silvered back of the mirror which is created by the clear substrate 1701 with silver coating 1703A, 1703B. When the light active sheet material 1707 is illuminated, light is emitted from the light active sheet material through the masked portion 1705.

Accordingly, a method of manufacturing a mirror with embedded lighting can include providing a clear substrate, wherein the clear substrate is to be used as a mirror; forming a mirror coating on the clear substrate, with an opening formed therein to provide an uncoated area of the clear substrate conforming to a shape of a light; providing a light active sheet material; disposing the light active sheet material on the clear substrate, so as to cover at least the uncoated area; and disposing a mirror base on the light active sheet material so as to cover the light active sheet material and the clear substrate. The light active sheet material comprises top and bottom electrically conductive transparent substrates, a pattern of light emitting diode (LED) chips sandwiched between the electrically conductive transparent substrates, and a non-conductive transparent adhesive material disposed between the top and bottom electrically conductive transparent substrates and the LED chips. One of the electrically conductive transparent substrates facing the clear substrate further is transparent. The LED chips are preformed before being patterned in the light active sheet material as an unpackaged discrete semiconductor device having an anode p-junction side and a cathode n-junction side, wherein either of the anode and the cathode side is in electrical communication with one of the electrically conductive transparent substrates and the other of the anode and the cathode side is in electrical communication with the other of the electrically conductive transparent substrates.

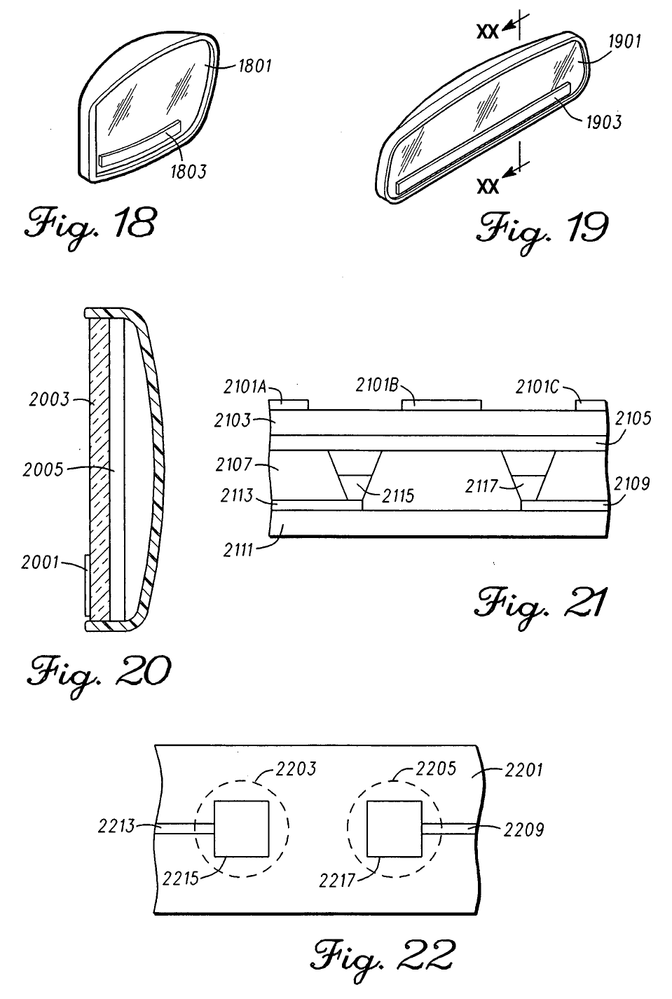

FIG. 18 and FIG. 19 provide examples of transparent lighting used with a side view mirror or rear view mirror, respectively. FIG. 20 provides a cross section of the mirror in FIG. 19.

Referring now to FIG. 18, an illustration of a transparent lighting used with a side view mirror will be discussed and described. A side view mirror 1801 is provided. A strip 1803 of transparent light active sheet material is adhered over a surface of the mirror 1801, to provide illumination.

Accordingly, in a mirror with transparent lighting for a conveyance, the LED chips can have red or white or amber or blue or green colors, and the color of LED chips in the pattern can be disposed in a pattern for use as a turn signal lighting system for the conveyance.

Referring now to FIG. 19, an illustration of a transparent lighting used with a rear view mirror will be discussed and described. A rear view mirror 1901 is provided. A strip 1903 of transparent light active sheet material is adhered over a surface of the mirror 1901, to provide illumination.

Accordingly, there is provided a mirror with transparent lighting for a conveyance, including a mirror for a conveyance; and a transparent light active sheet material with an adhesive disposed thereon, the transparent light active sheet material being attached by an adhesive adjacent to a lower edge of the mirror. The transparent light active sheet material comprises top and bottom electrically conductive transparent substrates, a pattern of light emitting diode (LED) chips sandwiched between the electrically conductive transparent substrates, and a non-conductive transparent adhesive material disposed between the top and bottom electrically conductive transparent substrates and the LED chips. The LED chips are preformed before being patterned in the light active sheet material as an unpackaged discrete semiconductor device having an anode p-junction side and a cathode n-junction side, wherein either of the anode and the cathode side is in electrical communication with one of the electrically conductive transparent substrates and the other of the anode and the cathode side is in electrical communication with the other of the electrically conductive transparent substrates.

Referring now to FIG. 20, a cross sectional view of the transparent lighting according to FIG. 19 will be discussed and described. In this configuration, a rear view mirror includes a mirror 2003 and a mirror backing 2005. A strip 2001 of transparent light active sheet material is adhered over a surface of the mirror 2003.

Accordingly, a method of providing a conveyance with mirror with a transparent lighting includes providing a mirror with a transparent lighting as discussed herein, mounting the mirror on the conveyance, and electrically connecting the transparent lighting to an electrical wiring harness of the conveyance.

Moreover, a method for providing a transparent lighting sheet on a mirror of a conveyance can include providing a transparent light active sheet material with an adhesive disposed thereon; and attaching, to a mirror of a conveyance, the transparent light active sheet material with the adhesive disposed thereon. The light active sheet material comprises top and bottom electrically conductive transparent substrates, a pattern of light emitting diode (LED) chips sandwiched between the electrically conductive transparent substrates, and a non-conductive transparent adhesive material disposed between the top and bottom electrically conductive transparent substrates and the LED chips. The LED chips are preformed before being patterned in the light active sheet material as an unpackaged discrete semiconductor device having an anode p-junction side and a cathode n-junction side, wherein either of the anode and the cathode side is in electrical communication with one of the electrically conductive transparent substrates and the other of the anode and the cathode side is in electrical communication with the other of the electrically conductive transparent substrates.

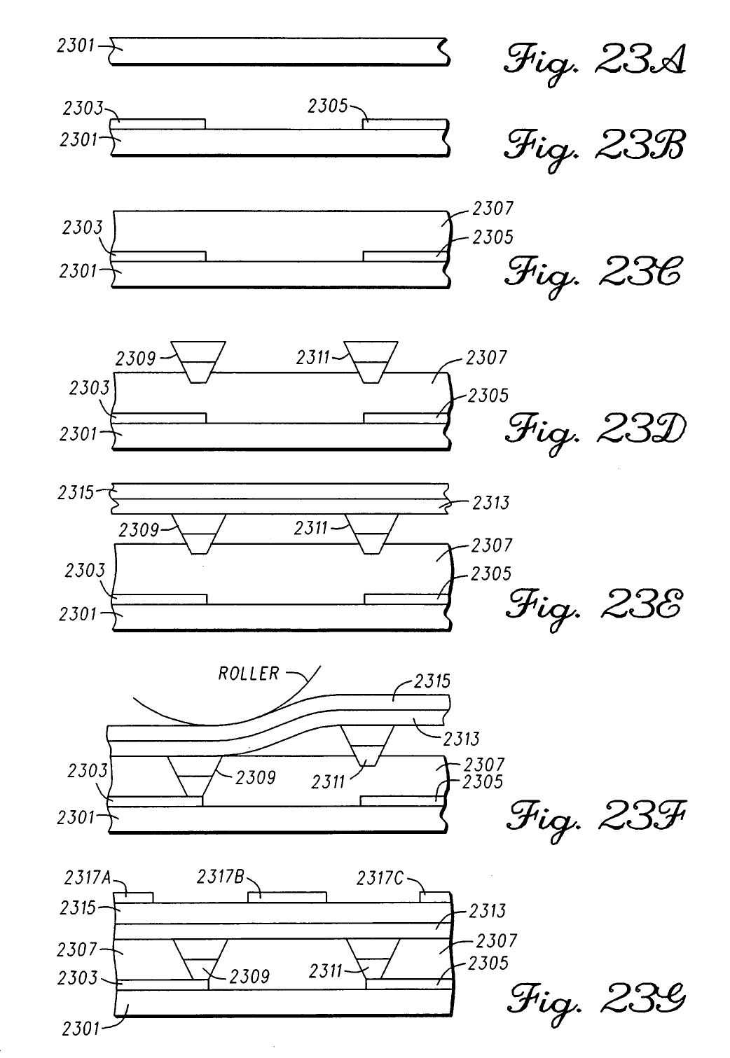

FIG. 21, FIG. 22, and FIG. 23A to FIG. 23G discuss a variation of a transparent light active sheet material where the conductor connecting the LED chips is a narrow line of conductive material, such as silver, provided on a transparent substrate. In contrast, in the light active sheet material discussed for example in FIG. 2, the conductor connecting the LED chips is provided by an electrically conductive transparent substrate. FIG. 21 is a cross section, FIG. 22 is a plan view, and FIG. 23A to FIG. 23G discuss an exemplary method for producing such a transparent light active sheet material.

Referring now to FIG. 21, a cross sectional view of transparent lighting on glass will be discussed and described. The transparent lighting on glass includes optional opaque material portions 2101A, 2101B, 2101C which are spaced apart; a transparent substrate 2103, an electrically conductive transparent substrate 2105, an adhesive material 2107, conductors 2109, 2113, LED chips 2115, 2117, and a transparent bottom substrate 2111.

The electrically conductive transparent substrate 2105 is disposed onto the transparent substrate 2103 prior to assembly of the light sheet. The electrically conductive transparent substrate 2105 is in direct electrical contact with the LED chips 2115, 2117. Also, the light from the LED chips 2115, 2117 will shine through the electrically conductive transparent substrate 2105 and the transparent substrate 2103. Accordingly, the electrically conductive transparent substrate 2105 can be formed of an electrically conductive material which is also optically transparent or translucent, such as those discussed above.

Each of the LED chips 2115, 2117 has a p-side and an n-side and/or light-to-energy semiconductor layered particles, wherein the n-side and the p-side correspond to charge donor and charge acceptor layers. The LED chips 2115, 2117 are oriented to be driven with the same polarity electrical energy. The LED chips 2115, 2117 are in electrical contact with the electrically conductive transparent substrate 2105 as well as respective conductors 2109, 2113 disposed below the LED chips 2115, 2117. Appropriate LED chips are widely available commercially. The LED chips 2115, 2117 are patterned on the conductors.

The conductors (here represented by conductors 2109, 2113), are formed of a conductive material, for example, conductive adhesive, conductive screen print, conductive film, or conductive wire. The conductors 2109, 2113 may be deposited and formed on the transparent substrate 2111 using various methods, such as masking, film deposition, etching, printing, or other variations. For example, silver ink can be printed and cured in locations which are to have a lower resistance path. Silver ink can be printed in very narrow lines (for example, 0.020 inches, or 0.5 mm) to form the conductors 2109, 2113 which carry electrical current to the individual LED chips 2115, 2117. In so doing, the light active sheet material can permit over half of the light emitted from the LED chips to pass through the light active sheet material. Thus, a light active sheet material can be manufactured that is transparent in over 95% of its surface area.

The transparent bottom substrate 2111 can be formed of a flexible transparent non-conductive material, for example, glass (in this example), plastic, a polymer, or any transparent non-conductive material.

The adhesive material 2107 is disposed to fill gaps between the patterned LED chips, gaps between the electrically conductive transparent substrate 2105 and the conductors 2109, 2113, and gaps between the electrically conductive transparent substrate 2105 and the transparent bottom substrate 2111. The adhesive material 2107 also mechanically holds together the transparent substrate 2103, the conductors 2109, 2113, and the bottom substrate 2111. The adhesive material 2107 electrically isolates the electrically conductive transparent substrate 2105 from the conductors 2109, 2115, and therefore the adhesive material can be formed of any non-conductive adhesive. The adhesive material 2107 further can be transparent.

The conductors 2109, 2113 have the opposite polarity, and are located below the LED chips 2109, 2113 are biased opposite of each other in series, and spaced apart from each other so that a gap is formed between the conductors. The conductors 2109, 2113, may be connected to a power source. In this configuration, a resistor is formed between the two LED chips 2109, 2113 by the electrically conductive transparent substrate 2111.

Although only two LED chips are illustrated, additional LED chips can be added and connected in series or in parallel using the above principles and extensions thereof, as will be appreciated by one of ordinary skill in the art. Although conductors 2109, 2113 are illustrated below the LED chips, the conductors could be applied to either or both transparent conductive substrates 2105, 2111, as will be appreciated.

The opaque material portions 2101A, 2101B, 2101C illustrated in FIG. 21 are optional. The opaque material portions 2101A, 2101B, 2101C can be screen printed onto the light active sheet material in order to control areas which are illuminated. This can permit thin panels to be used for instrumentations, as in an instrument panel in a vehicle.

Accordingly, a lighting system can include a transparent substrate, and a light active sheet material laminated on the transparent substrate. The light active sheet material comprises an electrically conductive transparent top substrate, a pattern of at least one light emitting diode (LED) chip sandwiched between the electrically conductive transparent top substrate and the transparent substrate, and a non-conductive transparent adhesive material disposed between the electrically conductive transparent top substrate, the transparent substrate, and the LED chips. A silver ink is printed and cured in locations on the transparent substrate to provide electrical current to individual LED chips. The at least one LED chip is preformed before being patterned in the light active sheet material as an unpackaged discrete semiconductor device having an anode p-junction side and a cathode n-junction side, wherein either of the anode and the cathode side is in electrical communication with the electrically conductive transparent top substrate and the other of the anode and the cathode side is in electrical communication with the silver ink.

According to one or more embodiments of the lighting system, the transparent substrate is glass.

Further accordingly, various embodiments of the lighting system also include a second transparent substrate, in contact with the electrically conductive transparent top substrate on a side opposite to the LED chip pattern; and an opaque layer screen-printed in a pattern, in contact with the second transparent substrate, wherein the opaque layer includes at least one opening corresponding to the at least one LED chip.

Referring now to FIG. 22, a plan view of the transparent lighting of FIG. 21 will be discussed and described. The transparent lighting includes a light sheet material 2201. An opaque material (not shown) with openings 2203, 2205 (whose position is shown by dashed lines) formed therein is positioned on the light sheet material 2201. LED chips 2215, 2217 in the light sheet material 2201 are positioned below the openings 2203, 2205 in the opaque material. Conductors 2209, 2213 can be masked, formed, printed, deposited, etched, or the like in the light sheet material 2201 so that the LED chips 2215, 2217 can be positioned in a desired pattern.

Referring now to FIG. 23A to FIG. 23G are cross sectional diagrams illustrating a method of producing the transparent lighting according to FIG. 21 and FIG. 22 will be discussed and described.

In FIG. 23A, a bottom transparent substrate 2301 is provided. In FIG. 23B, conductors 2303, 2305 are disposed on a bottom transparent substrate 2301. The conductors 2303, 2305 have a pattern corresponding to locations where LED chips will be patterned. Appropriate methods for providing the conductors 2303, 2305 include vapor deposition and etching, screen printing, electroplating, and the like. The conductors 2303, 2305 correspond to the conductors discussed in connection with FIG. 21 and FIG. 22.

In FIG. 23C, a non-conductive adhesive material 2307 is disposed on the bottom substrate 2301 and conductors 2303, 2305. The adhesive material 2307 can be provided as a film. The adhesive material corresponds to the adhesive material discussed in connection with FIG. 21 and FIG. 22.

As illustrated in FIG. 23D, the LED chips 2309, 2311 are patterned on the adhesive material 2307 in a predetermined pattern so that they are positioned on top of the conductors 2303, 2305. Also, the predetermined pattern can correspond to a particular shape and/or color of lighting for which the light sheet is to be used.

FIG. 23E illustrates a transparent substrate 2315, onto which an electrically conductive transparent substrate 2313 was previously disposed, as discussed in FIG. 22 and FIG. 23. The transparent substrate 2315 with electrically conductive transparent substrate 2313 is disposed over the LED chips 2309, 2311.

As illustrated in FIG. 23F, a roller presses together the transparent substrate 2315, the electrically conductive transparent substrate 2313, the adhesive material 2307, the LED chips 2309, 2311, the conductors 2303, 2305, and the bottom transparent substrate 2301. By use of pressure and/or heat, the LED chips can be sandwiched between and in electrical contact with the conductors 2303, 2305 and the electrically conductive transparent substrate 2313. Meanwhile, the adhesive material 2307, which is non-conductive, becomes distributed in the gaps between the conductors 2303, 2305, gaps between the bottom transparent substrate 2301 and the electrically conductive transparent substrate 2313, and gaps between the LED chips 2309, 2311.

FIG. 23G illustrates opaque material portions 2317A, 2317B, 2317C disposed on top of the transparent substrate 2315. These can be deposited by, for example, screen printing, etching, masking and deposition, painting, and other related techniques. Light emitted from the LED chips 2309 2311 will be blocked by the opaque material portions 2317A, 2317B, 2317C but will be emitted by gaps between the opaque material portions.

The light active sheet material can be formed as a lighting system for an automobile or a truck or other conveyance. Also, the LED chips can have red, white, amber, blue, or green colors (or a combination of two or more of the colors), and the color of LED chips in the pattern can be disposed in a pattern for use as one or-more lighting devices. Such the lighting devices can be a head light, a rear light, a rear window light, a side window light, a turn signal light, a high mount stop light, a side marker lamp, an under-mount lamp, or an emergency strobe light.

It should be noted that the term conveyance is used herein to indicate something which serves as a means of transportation. Examples of conveyances, as the term is used herein, include automobiles, trucks, buses, other motorized land vehicles such as ride-on lawn mowers, trains, air craft, water craft, heavy machinery used for regulated or non-regulated industries such as agricultural, lawn care, mining, snow blowing, trailers for use with the foregoing, and the like, and variants or evolutions thereof.

An LED chip utilized with the light active material can be organic (OLED) or inorganic (ILED), although testing shows that ILED chips are particularly preferable. Appropriate OLED and ILED chips are readily available from many manufacturers.

This disclosure is intended to explain how to fashion and use various embodiments in accordance with the invention rather than to limit the true, intended, and fair scope and spirit thereof. The invention is defined solely by the appended claims, as they may be amended during the pendency of this application for patent, and all equivalents thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

What is claimed is:

1. A transparent lighting system for a conveyance, comprising:
a transparent light active sheet material; and
an adhesive disposed on the transparent light active sheet material,
wherein the transparent light active sheet material comprises top and bottom electrically conductive transparent substrates, a pattern of light emitting diode (LED) chips sandwiched between the electrically conductive transparent substrates, and a non-conductive transparent adhesive material disposed between the top and bottom electrically conductive transparent substrates and the LED chips,
wherein the LED chips are preformed before being patterned in the light active sheet material as an unpackaged discrete semiconductor device having an anode p-junction side and a cathode n-junction side,
wherein either of the anode and the cathode side is in electrical communication with one of the electrically conductive transparent substrates and the other of the anode and the cathode side is in electrical communication with the other of the electrically conductive transparent substrates.

2. The system of claim 1,
wherein the transparent light active sheet material is formed as a lighting system for an automobile or motorcycle,
wherein the LED chips have red or white or amber or blue or green colors, and
wherein the color of LED chips in the pattern are disposed in a pattern for use as one or more lighting devices,
wherein the lighting devices are: a rear window lighting system, a side window lighting system, a turn signal lighting system, a high mount stop lighting system, a center high mount stop lighting system, a windshield outlining system, a side marker lamp system, or an emergency strobe light.

3. The system of claim 1,
wherein the transparent light active sheet material is formed as an advertisement for an automobile,
wherein the LED chips in the pattern are disposed in a pattern for use as one or more advertisements.

4. A method of providing a conveyance with a transparent lighting system, comprising:
providing a transparent lighting system as recited in claim 1;
mounting the transparent lighting system on the conveyance; and
electrically connecting the transparent lighting system to an electrical wiring harness of the conveyance.

5. The method of claim 4, wherein the transparent light system is mounted on a window of the conveyance.

6. The method of claim 4, wherein the transparent lighting system is mounted on a body panel of the conveyance.

7. A method for using a transparent lighting sheet on a conveyance, comprising:
providing a transparent light active sheet material;
disposing an adhesive sheet on the transparent light active sheet material, wherein the adhesive sheet has a size sufficient to attach the transparent light active sheet material to the conveyance; and
attaching, to the conveyance, the transparent light active sheet material with the adhesive sheet disposed thereon,
wherein the light active sheet material comprises top and bottom electrically conductive transparent substrates, a pattern of light emitting diode (LED) chips sandwiched between the electrically conductive transparent substrates, and a non-conductive transparent adhesive material disposed between the top and bottom electrically conductive transparent substrates and the LED chips,
wherein the LED chips are preformed before being patterned in the light active sheet material as an unpackaged discrete semiconductor device having an anode p-junction side and a cathode n-junction side,
wherein either of the anode and the cathode side is in electrical communication with one of the electrically conductive transparent substrates and the other of the anode and the cathode side is in electrical communication with the other of the electrically conductive transparent substrates.

8. The method of claim 7, further comprising shaping the transparent light active sheet material prior to attaching the transparent light active sheet material to the conveyance.

9. The method of claim 7, wherein the transparent light active sheet material is shaped as a lighting system for the conveyance,
wherein the LED chips have red or white or amber or blue or green colors, and
wherein the color of LED chips in the pattern are disposed in a pattern for use as one or more lighting devices,
wherein the lighting devices are: a rear window lighting system, a side window lighting system, a turn signal lighting system, a high mount stop lighting system, a center high mount stop lighting system, a windshield outlining system, a side marker lamp system, or an emergency strobe light,
wherein the lighting system is attached to a respective location on the conveyance.

10. The method of claim 7, further comprising:
mounting the lighting system on the conveyance; and
electrically connecting the lighting system to an electrical wiring harness of the conveyance.

11. A lighting system kit for attaching a transparent light sheet to a conveyance, comprising:
a transparent light active sheet material;
an adhesive sheet for attaching the transparent light active sheet material to the conveyance, wherein the adhesive sheet has a size sufficient to attach the transparent light active sheet material to the conveyance; and
instructions for shaping the transparent light active sheet material and attaching the transparent light active sheet material to the conveyance,
wherein the light active sheet material comprises top and bottom electrically conductive transparent substrates, a pattern of light emitting diode (LED) chips sandwiched between the electrically conductive transparent substrates, and a non-conductive transparent adhesive material disposed between the top and bottom electrically conductive transparent substrates and the LED chips,
wherein the LED chips are preformed before being patterned in the light active sheet material as an unpackaged discrete semiconductor device having an anode p-junction side and a cathode n-junction side,
wherein either of the anode and the cathode side is in electrical communication with one of the electrically conductive transparent substrates and the other of the anode and the cathode side is in electrical communication with the other of the electrically conductive transparent substrates.

12. The lighting system kit of claim 11,
wherein the transparent light active sheet material is formed as a lighting system for an automobile or motorcycle,
wherein the LED chips have red or white or amber or blue or green colors, and
wherein the color of LED chips in the pattern are disposed in a pattern for use as one or more lighting devices,
wherein the lighting devices are: a rear window lighting system, a side window lighting system, a turn signal lighting system, a high mount stop lighting system, a center high mount stop lighting system, a windshield outlining system, a side marker lamp system, or an emergency strobe light.

13. The lighting system kit of claim 11,
wherein the transparent light active sheet material is formed as an advertisement for an automobile,
wherein the LED chips in the pattern are disposed in a pattern for use as one or more advertisements.
